(19) United States
(12) Patent Application Publication
(10) Pub. No.: US 2025/0253759 A1
(43) Pub. Date: Aug. 7, 2025

(54) ELEMENT EVALUATION DEVICE

(71) Applicant: ROHM CO., LTD., Kyoto-shi (JP)

(72) Inventors: Kei SENGA, Kyoto-shi (JP); Seiya KITAGAWA, Kyoto-shi (JP)

(73) Assignee: ROHM CO., LTD., Kyoto-shi (JP)

(21) Appl. No.: 19/094,993

(22) Filed: Mar. 30, 2025

Related U.S. Application Data
(63) Continuation of application No. PCT/JP2023/028270, filed on Aug. 2, 2023.

(30) Foreign Application Priority Data
Sep. 30, 2022 (JP) 2022-157350

(51) Int. Cl. H02M 1/088; H02M 3/155; H03K 17/10

(52) U.S. Cl. CPC H02M 1/088; H02M 3/155; H03K 17/102

(57) ABSTRACT

An element evaluation device includes a target element connected between first and second nodes; a drive switching element connected between the second node and a third node; an inductor connected between the second node and a fourth node applied with a power supply voltage; a switching circuit that allows the drive switching element to perform switching, a voltage generation circuit connected between the first and fourth nodes, and a capacitor connected between the first and third nodes. After the drive switching element is turned off, when a circulation current flows from the fourth node back to the fourth node via the second node, the first node, and the voltage generation circuit, the voltage generation circuit generates a voltage between the first and fourth nodes, with the first node being a high potential side.

### CROSS-REFERENCE TO RELATED APPLICATIONS

This nonprovisional application is a continuation application of International Patent Application No. PCT/JP2023/028270 filed on Aug. 2, 2023, which claims priority to Japanese Patent Application No. 2022-157350 filed on Sep. 30, 2022, the entire contents of each are hereby incorporated by reference.

### TECHNICAL FIELD

The present disclosure relates to an element evaluation device.

### BACKGROUND ART

A rapid change of voltage applied to a semiconductor element may obstruct normal operation of the semiconductor element or may cause deterioration of the semiconductor element. For instance, a variation along time of a drain-source voltage of a MOSFET is usually referred to as dV/dt, and a high dV/dt may obstruct normal operation of the MOSFET or may cause deterioration of the MOSFET. A tolerance for dV/dt can be evaluated by a double pulse test or the like.

### LIST OF CITATIONS

### Patent Literature

Patent Document 1: JP-A-2019-176078

### BRIEF DESCRIPTION OF DRAWINGS

FIG. 1 is a circuit diagram of a reference evaluation device.

FIG. 2 is a circuit diagram of an element evaluation device according to a first embodiment of the present disclosure.

FIG. 3 is a diagram illustrating a waveform of a gate signal and a state transition of a transistor that receives the gate signal, according to the first embodiment of the present disclosure.

FIG. 4 is an explanatory diagram of an operation of the element evaluation device according to the first embodiment of the present disclosure.

FIG. 5 is an explanatory diagram of the operation of the element evaluation device according to the first embodiment of the present disclosure.

FIG. 6 is an explanatory diagram of the operation of the element evaluation device according to the first embodiment of the present disclosure.

FIG. 7 is a schematic external diagram of a semiconductor component according to the first embodiment of the present disclosure.

FIG. 8 is a circuit diagram of the transistor and its vicinity, which includes an equivalent circuit of the semiconductor component, according to the first embodiment of the present disclosure.

FIG. 9 is a circuit diagram of the element evaluation device according to a second embodiment of the present disclosure.

FIG. 10 is a modified circuit diagram on the basis of the element evaluation device of FIG. 2, according to a third embodiment of the present disclosure.

FIG. 11 is a modified circuit diagram on the basis of the element evaluation device of FIG. 2, according to the third embodiment of the present disclosure.

### DESCRIPTION OF EMBODIMENTS

Hereinafter, an example of an embodiment of the present disclosure is described specifically with reference to the drawings. In the drawings that are referred to, the same part is denoted by the same numeral or symbol, and overlapping description of the same part is omitted as a rule. Note that in this specification, for simple description, by referring to a symbol or a code of information, a signal, a physical quantity, a functional unit, a circuit, an element, a component, or the like, a name of the information, the signal, the physical quantity, the functional unit, the circuit, the element, the component, or the like may be omitted or abbreviated.

First, some terms used in the description of the embodiment of the present disclosure are explained below. A ground means a reference conductive part having a potential of 0 V (zero volts) to be a reference, or means the 0 V potential itself. The reference conductive part may be formed of a conductor such as metal. The 0 V potential may be referred to as a ground potential. In the embodiment of the present disclosure, a voltage without a specific reference means a potential with reference to the ground. A level means a potential level, and for an arbitrary noted signal or voltage, a high level has a higher potential than a low level.

For an arbitrary transistor constituted as a field effect transistor (FET) including a MOSFET, ON state means a conducting state between source and drain of the transistor, while OFF state means a non-conducting state (cut-off state) between source and drain of the transistor. The same is true for a transistor that is not classified as an FET. Unless otherwise noted, MOSFET is understood as an enhancement type MOSFET. MOSFET is abbreviation of “metal oxide semiconductor field effect transistor”. In addition, unless otherwise noted, in an arbitrary MOSFET, it can be considered that the backgate is short-circuited to the source. In an arbitrary transistor constituted as a MOSFET, a gate-source voltage means a gate potential with respect to a source potential.

In the following description, for an arbitrary transistor, ON state and OFF state may be simply expressed as ON and OFF, respectively. For an arbitrary transistor, switching from OFF state to ON state is expressed as turning on, and switching from ON state to OFF state is expressed as turning off. In addition, for an arbitrary transistor, a period while the transistor is in ON state may be referred to as ON period, and a period while the transistor is in OFF state may be referred to as OFF period.

A connection between a plurality of parts forming a circuit, such as arbitrary circuit elements, wirings (lines), nodes, and the like, may be understood to mean an electric connection, unless otherwise noted.

### First Embodiment

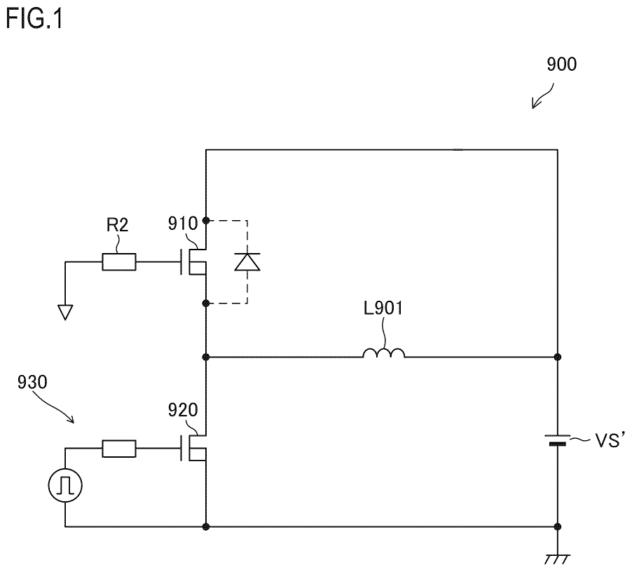

A first embodiment of the present disclosure is described below. Before description of a structure of the first embodiment, a reference evaluation device 900 is described with reference to FIG. 1. FIG. 1 is a circuit diagram of the reference evaluation device 900. The reference evaluation device 900 includes transistors 910 and 920, which are N-channel type MOSFETs. A positive power supply voltage is applied to the drain of the transistor 910 from a voltage source VS′. In addition, an inductor L901 is inserted between a positive output terminal of the voltage source VS' and a connection node between the source of the transistor 910 and the drain of the transistor 920. The source of the transistor 920 is connected to the ground. A predetermined potential for fixing the transistor 910 in OFF state is applied to the gate of the transistor 910. A switching circuit 930 supplies a gate signal for switching the transistor 920, to the gate of the transistor 920.

During ON period of the transistor 920, a current flows from the voltage source VS' through the inductor L901 and the channel of the transistor 920, and hence energy is stored in the inductor L901. After that, when the transistor 920 is turned off, a circulation current based on the energy stored in the inductor L901 flows in a current loop that goes through the inductor L901 and a parasitic diode of the transistor 910.

During switching of the transistor 920, the drain-source voltage of the transistor 910 is changed. A rapid change of the drain-source voltage of the transistor 910 can have an unwanted effect on the transistor 910. The reference evaluation device 900 repeats turning on and off of the transistor 920, so that tolerance of the transistor 910 for changes of the drain-source voltage (dV/dt) can be evaluated.

The reference evaluation device 900 is one type of a double pulse test circuit. In a general double pulse test circuit, it is difficult to obtain a sufficiently high dV/dt. In addition, it is also difficult to increase a switching frequency, which has a limit of approximately 2 kHz (kilohertz).

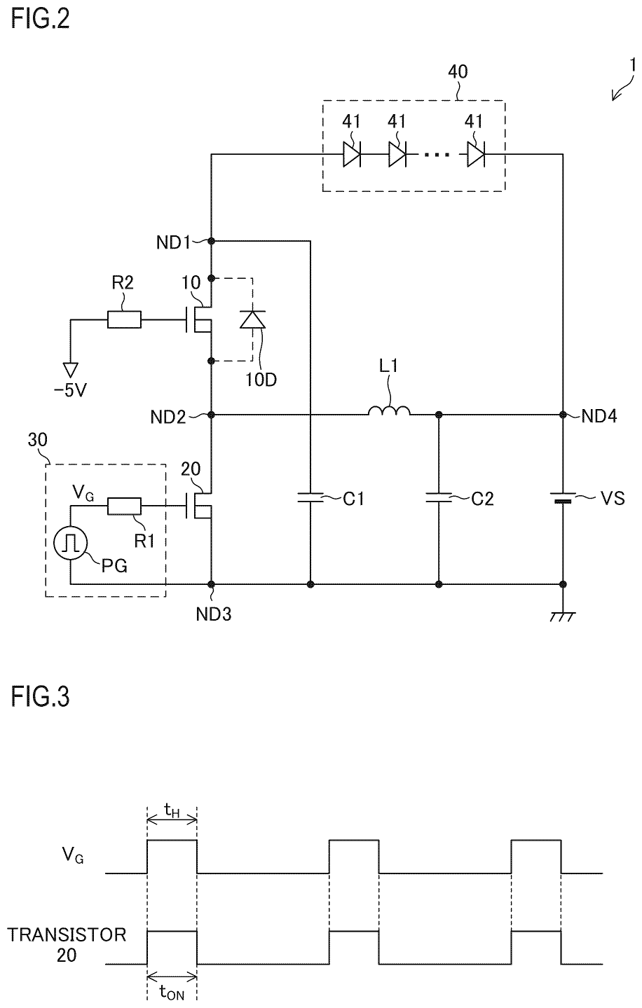

FIG. 2 illustrates a circuit diagram of an element evaluation device 1 according to the first embodiment. The element evaluation device 1 includes a voltage source VS, a transistor 10 (a target transistor) that is a high-side transistor, a transistor 20 (a drive switching element) that is a low-side transistor, a switching circuit 30, a voltage generation circuit 40, an inductor L1, capacitors C1 and C2, and a resistor R2.

The transistors 10 and 20 are N-channel type MOSFETs. The transistor 10 is connected between nodes ND1 and ND2, and the transistor 20 is connected between the node ND2 and a node ND3. More specifically, the drain of the transistor 10 is connected to the node ND1, the source of the transistor 10 and the drain of the transistor 20 are commonly connected to the node ND2, and the source of the transistor 20 is connected to the node ND3. The node ND3 is connected to the ground, and hence has the ground potential. In FIG. 2, a diode 10D is a parasitic diode that is added the transistor 10. The parasitic diode 10D has an anode connected to the source of the transistor 10 and a cathode connected to the drain of the transistor 10.

In FIG. 2, the transistor 10 is a semiconductor element whose tolerance for dV/dt is to be evaluated, and is an example of a target element. In this embodiment, dV/dt indicates a variation of voltage between the nodes ND1 and ND2 per unit time. In the case where the target element is the transistor 10, the voltage between the nodes ND1 and ND2 is the drain-source voltage of the transistor 10. The tolerance for dV/dt of the target element may be referred to as a dV/dt tolerance in the following description. Note that the tolerance may be read as endurance.

The gate of the transistor 10 is connected to a fixed potential terminal having a predetermined fixed potential (e.g., −5 V), via the gate resistor R2. In the element evaluation device 1, because the gate potential of the transistor 10 is set to the fixed potential, the transistor 10 is fixed to OFF state. However, the gate resistor R2 can be omitted, and the gate of the transistor 10 can be directly connected to the above fixed potential terminal.

The switching circuit 30 has a pulse generator PG and a gate resistor R1. The switching circuit 30 drives the gate of the transistor 20 so as to allow the transistor 20 to perform switching, or in other words, it switches the state of the transistor 20 between ON state and OFF state. During switching of the transistor 20, dV/dt more than 0 V can be generated.

The pulse generator PG has a signal output terminal and a reference potential terminal connected to the node ND3 (i.e., the ground), and outputs a high level or low level signal from the signal output terminal. The signal output from the signal output terminal of the pulse generator PG is referred to as a gate signal V_{G} in the following description. The gate signal V_{G} is supplied to the gate of the transistor 20. The gate signal V_{G} of high level has a potential higher than the threshold voltage of the gate of the transistor 20. The gate signal V_{G} of low level has a potential lower than the threshold voltage of the gate of the transistor 20, and it is 0 V here. When the gate signal V_{G} has high level, the transistor 20 is in ON state. When the gate signal V_{G} has low level, the transistor 20 is in OFF state.

The pulse generator PG changes the level of the gate signal V_{G} alternately and periodically between high level and low level. FIG. 3 illustrates a waveform of the gate signal V_{G} and a state transition of the transistor 20. The frequency of the gate signal V_{G} is referred to as the switching frequency. The frequency of the gate signal V_{G} is also the switching frequency of the transistor 20. In each period of the gate signal V_{G}, the time length while the gate signal V_{G} has high level is a time period t_{H}. In each period of the gate signal V_{G}, the length of ON period of the transistor 20 is a time period t_{ON}. When regarding that a turn-on delay time and a turn-off delay time of the transistor 20 are short enough to omit the same, “t_{H}=t_{ON}” holds.

The signal output terminal of the pulse generator PG is connected to the gate of the transistor 20 via the gate resistor R1. In the element evaluation device 1, the gate resistor R1 may be a variable resistor. By changing the resistance value of the gate resistor R1, dV/dt of the transistor 10 can be changed.

The voltage source VS has a positive output terminal connected to a node ND4 and a negative output terminal connected to the node ND3 (i.e., to the ground). The voltage source VS outputs a positive power supply voltage VDD from the positive output terminal, with respect to the potential at the negative output terminal. For this reason, the power supply voltage VDD is applied to the node ND4. The voltage source VS may be a variable voltage source whose power supply voltage VDD is variable. Also to obtain high dV/dt, the power supply voltage VDD is preferably set to 600 V or more.

The inductor L1 is connected between the nodes ND2 and ND4. More specifically, a first end of the inductor L1 is connected to the node ND2, and a second end of the inductor L1 is connected to the node ND4.

The capacitor C1 is connected between the nodes ND1 and ND3. More specifically, a first end of the capacitor C1 is connected to the node ND1, and a second end of the capacitor C1 is connected to the node ND3. The capacitor C2 is connected between the nodes ND4 and ND3. More specifically, a first end of the capacitor C2 is connected to the node ND4, and a second end of the capacitor C2 is connected to the node ND3.

The voltage generation circuit 40 is connected between the node ND1 and ND4. The voltage generation circuit 40 is constituted of one or more rectifying diodes 41. Each rectifying diode 41 in the voltage generation circuit 40 has a forward direction from the node ND1 to the node ND4. If the voltage generation circuit 40 is constituted of a plurality of rectifying diodes 41, the plurality of rectifying diodes 41 are connected in series to each other between the node ND1 and the node ND4. Therefore, for example, if the voltage generation circuit 40 is constituted of the first to third rectifying diodes 41, the anode of the first rectifying diode 41 is connected to the node ND1, the cathode of the first rectifying diode 41 is connected to the anode of the second rectifying diode 41, the cathode of the second rectifying diode 41 is connected to the anode of the third rectifying diode 41, and the cathode of the third rectifying diode 41 is connected to the node ND4. If the voltage generation circuit 40 is constituted of a single rectifying diode 41, the anode of the single rectifying diode 41 is connected to the node ND1, and the cathode of the single rectifying diode 41 is connected to the node ND4.

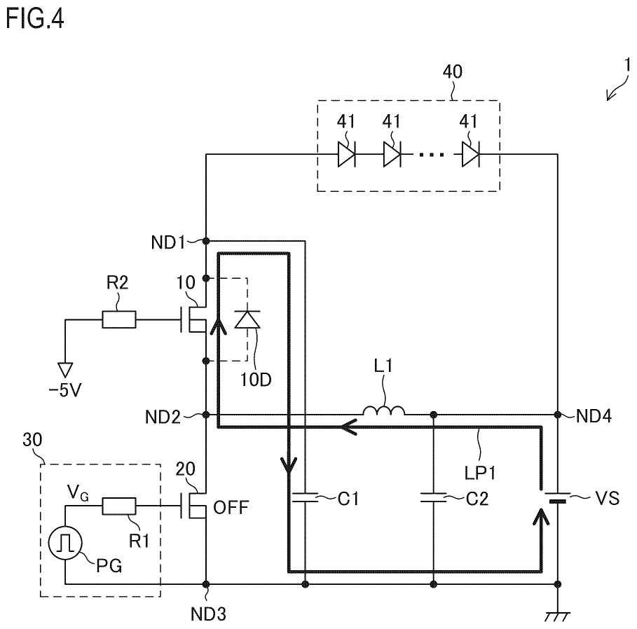

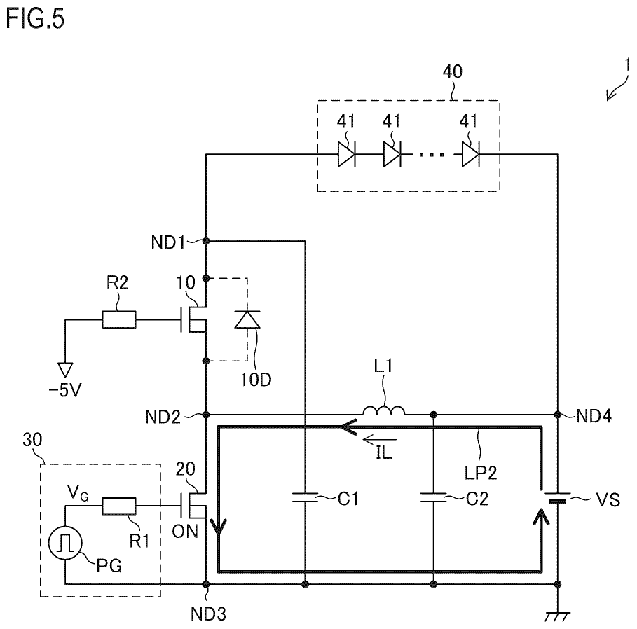

An operation of the element evaluation device 1 is described below. The starting point is considered to be when the transistor 20 is in OFF state. When the transistor 20 is in OFF state, as illustrated in FIG. 4, a current flows in a current loop LP1 from the node ND4 to the node ND3 via the inductor L1, the parasitic diode 10D, and the capacitor C1, and back to the node ND4 via the voltage source VS or the capacitor C2. The current flowing in the current loop LP1 charges the capacitor C1. The charging is performed until the voltage across the capacitor C1 reaches the power supply voltage VDD, and then the current flowing in the current loop LP1 becomes zero (here, the forward voltage of the parasitic diode 10D is smaller enough than the power supply voltage VDD, and it is omitted).

After that, the transistor 20 is turned on when receiving the gate signal V_{G} of high level from the switching circuit 30. When the transistor 20 is turned on, the potential of the node ND2 drops to substantially 0 V, and as illustrated in FIG. 5, a current flows in a current loop LP2 from the node ND4 to the node ND3 via the inductor L1 and the channel of the transistor 20, and back to the node ND4 via the voltage source VS or the capacitor C2. The current flowing in the current loop LP2 allows the inductor L1 to store energy. The current flowing in the current loop LP2 increases along with an increase in the ON time of the transistor 20, and the energy stored in the inductor L1 increases along with an increase in the current in the current loop LP2. The current flowing in the inductor L1 from the node ND4 to the node ND2 is referred to as an inductor current IL in the following description.

When the transistor 20 is turned on, the capacitance between the nodes ND1 and ND2 is charged on the basis of the voltage across the capacitor C1, and during the period of this charging, a high dV/dt is generated. The capacitance between the nodes ND1 and ND2 is a capacitance C_{DS} (not shown) between drain and source of the transistor 10. Specifically, when the transistor 20 is turned on, an output capacitance C_{OSS} of the transistor 10 is charged, and during the period of charging the output capacitance C_{OSS} of the transistor 10, a high dV/dt is generated. The output capacitance C_{OSS} of the transistor 10 is the sum of the capacitance C_{DS} between drain and source of the transistor 10 and a capacitance C_{GD} (not shown) between gate and drain of the transistor 10. The capacitances C_{DS} and C_{GD} are parasitic capacitances added to the transistor 10, and are not illustrated in FIG. 2, FIG. 5, and the like. The capacitance value of the capacitor C1 is sufficiently larger than that of the output capacitance C_{OSS}. Therefore, when the transistor 20 is turned on, the charge stored in the capacitor C1 increases the voltage across the capacitance Cos to substantially the power supply voltage VDD.

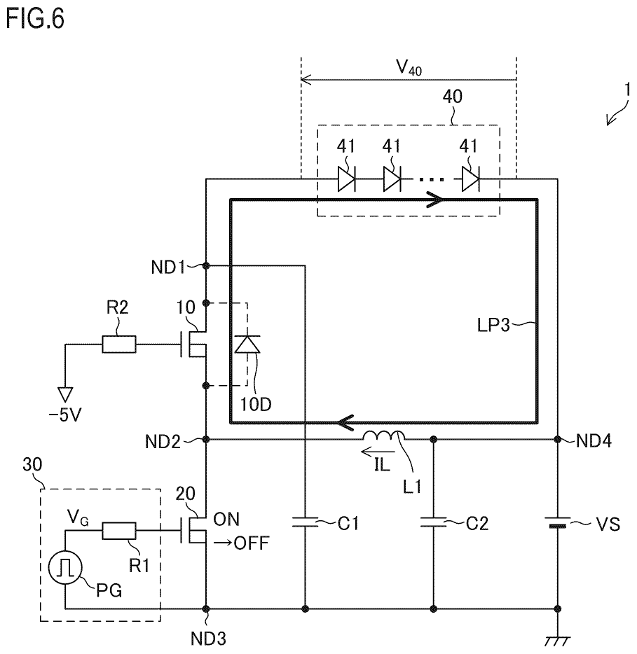

Further after that, the gate signal V_{G} from the switching circuit 30 is changed from high level to low level, and hence the transistor 20 is turned off. When the transistor 20 is turned off, a circulation operation is performed. In the circulation operation, as illustrated in FIG. 6, on the basis of the energy stored in the inductor L1, the inductor current IL flows in a current loop LP3 from the node ND4 back to the node ND4 via the inductor L1, the node ND2, the parasitic diode 10D, the node ND1, and the voltage generation circuit 40. Also when the transistor 20 is turned off, a high dV/dt is generated.

The inductor current IL flowing in the current loop LP3 is referred to as the circulation current. After the transistor 20 is turned off, the inductor current IL (the circulation current) flows in the current loop LP3, and hence the energy stored in the inductor L1 is being decreased. When the energy stored in the inductor L1 becomes zero, the inductor current IL flowing in the current loop LP3 becomes zero, and the state of FIG. 4 is restored. In the circulation operation, the voltage generation circuit 40 generates a voltage drop V₄₀ in which the node ND4 is a low potential side while the node ND1 is a high potential side. The voltage drop V₄₀ corresponds to the product of the total number of the rectifying diodes 41 and the forward voltage of each rectifying diode 41.

An example of specific numeric values in the element evaluation device 1 is described below. For instance, the power supply voltage VDD is 800 V, the inductance value of the inductor L1 is 50 μH (microhenries), the capacitance value of the capacitor C1 is 0.47 μF (microfarads), and the capacitance value of the capacitor C2 is 10 μF. The voltage drop V₄₀ in the circulation operation is 30 V, for example. The present disclosure is not limited to these numeric values.

When a specific dV/dt is applied to the target element, the time period while the target element endures is evaluated, and hence tolerance of the target element for the specific dV/dt can be known. Further, by changing dV/dt variously, it is possible to obtain a life curve of the target element (a curve obtained by plotting the time periods while the target element can endure for various dV/dt).

If a sufficiently high dV/dt can be generated, it is possible to evaluate tolerance of the target element for the high dV/dt. In order to obtain the high dV/dt, it is useful to increase speed of the transistor 20. Therefore, in this embodiment, an SiC-MOSFET is used as the transistor 20. The SiC-MOSFET is a MOSFET formed of silicon carbide (SiC). The transistor 20 may be an arbitrary type of switching element (drive switching element), and it is preferred to use a MOSFET having a turn-on delay time of 5 ns (nanoseconds) or less as the transistor 20, in order to obtain the high dV/dt. Further, it is preferred to perform driver source drive of the transistor 20 with the switching circuit 30 (meaning of the driver source drive will be described later).

By using the SiC-MOSFET having a turn-on delay time of 5 ns (nanoseconds) or less as the transistor 20, and by performing the driver source drive of the transistor 20, it is possible to obtain dV/dt having magnitude of 150 kV/μs, in the above example of numeric values. Note that the turn-on delay time of the transistor 20 is a delay time after a voltage higher than the threshold voltage of the gate of the transistor 20 is applied to between the gate and the source of the transistor 20, until the state of the transistor 20 is changed from OFF state to ON state, and it is a time period prescribed in specification of electric characteristics of the transistor 20.

In addition, in either the reference evaluation device 900 or the element evaluation device 1, in order to evaluate the dV/dt tolerance (such as the life curve) of the target element in a short period of time, it is necessary to increase the switching frequency. In the evaluation of the dV/dt tolerance of the target element (910) by the reference evaluation device 900, in order to generate dV/dt necessary in each period of the switching, after the transistor 920 is turned off, it is necessary to allow the transistor 920 to wait the next turning on, until the current of the inductor L901 is decreased to zero (it is necessary to reset the state of the reference evaluation device 900). In the same manner, in the evaluation of the dV/dt tolerance of the target element (10) by the element evaluation device 1, in order to generate dV/dt necessary in each period of the switching, after the transistor 20 is turned off, it is necessary to allow the transistor 20 to wait the next turning on, until the inductor current IL is decreased to zero (it is necessary to reset the state of the element evaluation device 1).

It is particularly noted that in the element evaluation device 1, the voltage generation circuit 40 is added, compared with the reference evaluation device 900. As described above, the voltage generation circuit 40 generates the voltage drop V₄₀ in the circulation operation (see FIG. 6). Due to generation of the voltage drop V₄₀, the speed of consuming the energy stored in the inductor L1 is increased, and the time period after the transistor 20 is turned off until the inductor current IL is decreased to zero is shortened. In other words, the time period necessary for the above waiting is shorter in the element evaluation device 1 than in the reference evaluation device 900. As a result, the switching frequency can be increased. Specifically, in the above example of numeric values, the circulation operation generates the voltage drop V₄₀ of approximately 30 V, and hence the switching frequency can be increased to approximately 30 kHz.

However, because the voltage generation circuit 40 constituted of the rectifying diodes 41 is provided, the charging current of the output capacitance C_{OSS} from the voltage source VS through the voltage generation circuit 40 is blocked by the rectifying diodes 41. Therefore, it is necessary to provide an additional circuit element for charging the output capacitance C_{OSS} of the transistor 10. In the element evaluation device 1, the capacitor C1 is provided as the above circuit element.

As long as the voltage drop V₄₀ having necessary voltage can be obtained, the number of the rectifying diodes 41 connected in series in the voltage generation circuit 40 is arbitrary. If a diode having sufficiently large forward voltage is used as the rectifying diode 41, the total number of the rectifying diodes 41 can be one.

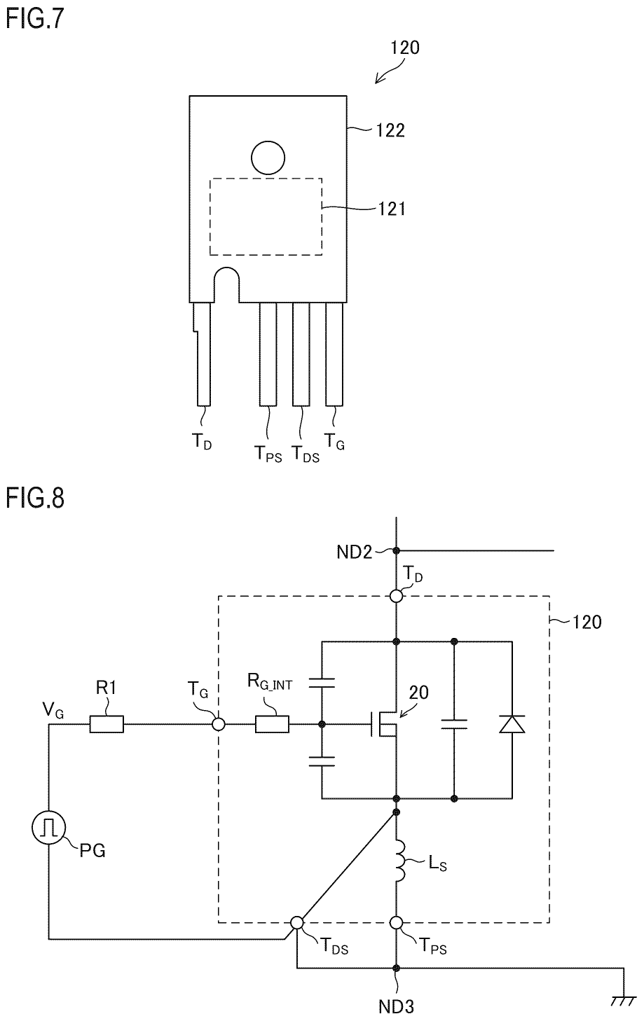

The driver source drive of the transistor 20 is described below. FIG. 7 is a schematic external diagram of a semiconductor component 120 including the transistor 20. The semiconductor component 120 includes a semiconductor chip 121 in which a MOSFET is formed, a package 122 made of resin as a case for housing the semiconductor chip 121, and four metal terminals T_{D}, T_{PS}, T_{DS}, and T_{G}, which are exposed from the package 122. The metal terminals T_{D}, T_{DS}, T_{DS}, and T_{G} are a drain terminal, a power source terminal, a driver source terminal, and a gate terminal, respectively. In particular, the power source terminal may be constituted of a plurality of metal terminals.

The MOSFET formed in the semiconductor chip 121 is an N-channel type MOSFET, and corresponds to the transistor 20. FIG. 8 is a circuit diagram of the transistor 20 and its vicinity, which includes an equivalent circuit of the semiconductor component 120.

Two separate N-type semiconductor regions are formed in the semiconductor chip 121, and one of the N-type semiconductor regions is a source region while the other is a drain region. A source electrode is formed on the source region, and a drain electrode is formed on the drain region. The source region and the source electrode in the semiconductor chip 121 form the source of the transistor 20, and the drain region and the drain electrode in the semiconductor chip 121 form the drain of the transistor 20. In the semiconductor chip 121, a P-type semiconductor region is disposed between the source region and the drain region, and a gate electrode is formed on the P-type semiconductor region via a gate oxide film. The gate electrode in the semiconductor chip 121 forms the gate of the transistor 20.

The gate electrode of the MOSFET in the semiconductor chip 121 is connected to the gate terminal T_{G} in the package 122. The gate terminal T_{G} is connected to the signal output terminal of the pulse generator PG via the gate resistor R1 in the outside of the semiconductor component 120. In FIG. 8, a resistor R_{G_INT} is a resistance component in the package 122, and it indicates a resistance component between the gate electrode and the gate terminal T_{G} of the transistor 20.

The drain electrode of the MOSFET in the semiconductor chip 121 is connected to the drain terminal T_{D} in the package 122. The drain terminal T_{D} is connected to the node ND2 in the outside of the semiconductor component 120. In other words, the drain electrode of the MOSFET in the semiconductor chip 121 is connected to the node ND2 via the drain terminal T_{D}.

The source electrode of the semiconductor chip 121 is connected to the power source terminal T_{DS} in the package 122. Here, the power source terminal T_{DS} has a relatively large inductance component. The inductance component included in the power source terminal T_{DS} is referred to as a package inductance component L_{S}. The source electrode of the semiconductor chip 121 is connected to the node ND3 via the power source terminal T_{DS} including the package inductance component L_{S}. The current flows in the current loop LP2 (FIG. 5) through the drain terminal T_{D} and the power source terminal T_{DS}. When the drain current of the transistor 20 changes along with switching of the transistor 20, the package inductance component L_{S} generates an electromotive force.

If the gate signal V_{G} is applied to between the power source terminal T_{DS} and the gate terminal T_{G}, the switching speed of the transistor 20 is decreased by an influence of the above electromotive force. In this embodiment, the source electrode of the semiconductor chip 121 is connected to the driver source terminal T_{DS} without going through the power source terminal T_{DS}. There is not the package inductance component L_{S} between the source electrode and the driver source terminal T_{DS} of the semiconductor chip 121. For this reason, the voltage between the gate electrode and the source electrode for driving the transistor 20 is not affected by the package inductance component L_{S}. Therefore, the switching speed of the transistor 20 can be increased.

As illustrated in FIG. 8, the driver source drive means that the reference potential terminal of the pulse generator PG is connected to the driver source terminal T_{DS}, and that the gate signal V_{G} is applied to between the gate terminal T_{G} and the driver source terminal T_{DS}, so as to allow the transistor 20 to perform switching. Note that in FIG. 8, illustration of package inductance components of the gate terminal T_{G} and the drain terminal T_{D} is omitted. It can be understood that the driver source terminal T_{DS} also includes an inductance component, but the inductance component included in the driver source terminal T_{DS} is sufficiently smaller than the package inductance component L_{S}.

In addition, as described above, in the evaluation of the dV/dt tolerance of the target element (10) by the element evaluation device 1, in order to generate dV/dt necessary in each period of the switching, after the transistor 20 is turned off, it is necessary to allow the transistor 20 to wait the next turning on, until the inductor current IL is decreased to zero (it is necessary to reset the state of the element evaluation device 1). In order to shorten the time period for this waiting, it is advantageous to control the peak value of the inductor current IL to be small, and the peak value of the inductor current IL is decreased by shortening the ON time T_{ON} of the transistor 20 (see FIG. 3). However, considering stability and the like of operation of the entire circuit, the ON time T_{ON} of the transistor 20 needs a certain degree of length. On the other hand, if the peak value of the inductor current IL is too large, heat generation amount in each rectifying diode 41 can be a problem. Considering these factors comprehensively, it is preferred to set the time period to to 500 ns (nanoseconds) or less, for example.

In addition, for example, the switching circuit 30 preferably allows the transistor 20 to perform switching at the switching frequency of 10 kHz (kilohertz) or more. In other words, the frequency of the gate signal V_{G} is preferably 10 kHz or more. In this way, it is possible to evaluate the dV/dt tolerance of the target element (10) in a short period of time.

Note that it may be possible that a high-side switching circuit (not shown) connected to the gate and the source of the transistor 10 is disposed in the element evaluation device 1, and that the high-side switching circuit supplies a signal to between the gate and the source of the transistor 10, so as to allow the transistor 10 to perform switching. In this case, the high-side switching circuit performs synchronous rectification in cooperation with the switching circuit 30, so that the transistor 10 is in OFF state when the transistor 20 is in ON state, and that the transistor 10 is in ON state when the transistor 20 is in OFF state. However, when this synchronous rectification is performed, decreasing speed of the inductor current IL flowing in the current loop LP3 (see FIG. 6) is lowered by the voltage drop of the parasitic diode 10D. Therefore, it is usually preferred not to perform the above synchronous rectification.

### Second Embodiment

A second embodiment of the present disclosure is described below. The second embodiment and a third embodiment described later are embodiments based on the first embodiment, and regarding matters that are not particularly noted in the second or third embodiment, the description in the first embodiment is applied also to the second or third embodiment, unless any contradiction arises. However, when reading the description in the second embodiment, regarding a matter conflicting between the first and second embodiments, description in the second embodiment may have priority (the same is true in the third embodiment described later). Unless any contradiction arises, any embodiments among the first to third embodiments may be combined.

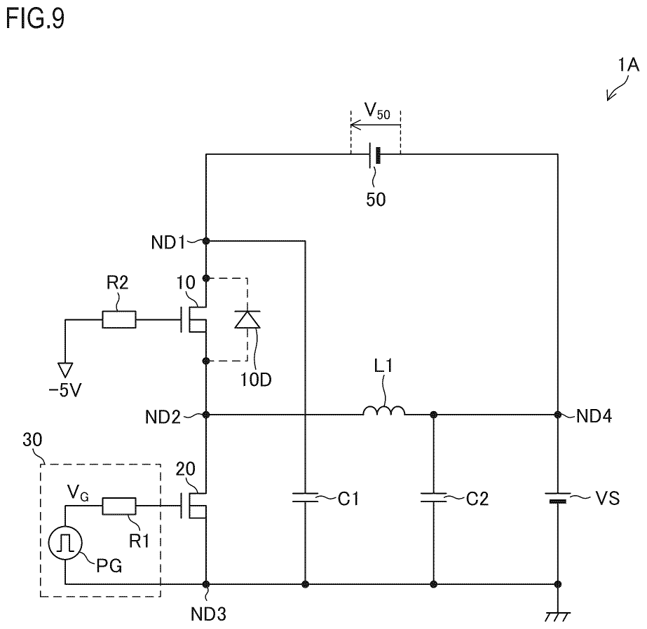

FIG. 9 illustrates a circuit diagram of an element evaluation device 1A according to the second embodiment. The element evaluation device 1A is obtained, on the basis of the element evaluation device 1 of FIG. 2, by replacing the voltage generation circuit 40 with a voltage generation circuit 50. Except for this replacement, the element evaluation device 1A of FIG. 9 has the same structure as the element evaluation device 1 of FIG. 2.

The voltage generation circuit 50 is a DC voltage source inserted between the nodes ND4 and ND1. A negative output terminal and a positive output terminal of the DC voltage source as the voltage generation circuit 50 are connected to the nodes ND4 and ND1, respectively. The voltage generation circuit 50 outputs a positive predetermined voltage V₅₀ (e.g., 30 V) to the node ND1, with respect to the potential of the node ND4. Therefore, similarly to the voltage generation circuit 40 according to the first embodiment, in the circulation operation (see FIG. 6), the voltage generation circuit 50 generates the voltage V₅₀ in which the node ND4 is the low potential side while the node ND1 is the high potential side. For this reason, the second embodiment can also provide the same action and effect as the first embodiment.

The DC voltage source as the voltage generation circuit 50 may be an arbitrary DC voltage source on the market, but it is necessary to prepare one having a withstand voltage equal to the power supply voltage VDD or higher with respect to the ground. Alternatively, it may be possible to use a floating power supply device as the voltage generation circuit 50.

### Third Embodiment

The third embodiment of the present disclosure is described below. The target element is a semiconductor element whose dV/dt tolerance is to be evaluated.

The target element may be an arbitrary type of transistor. A transistor as the target element is referred to as a target transistor in the following description. The transistor 10 described above is an example of the target transistor, and it can be expressed as the target transistor 10 in the following description.

In the first and second embodiments, semiconductor material for forming the target transistor 10 is arbitrary. In other words, for example, the target transistor 10 may be an SiC-MOSFET, or may be a MOSFET made of silicon. The target transistor 10 may be a super junction MOSFET. In any case, the target transistor 10 has the drain connected to the node ND1 and the source connected to the node ND2.

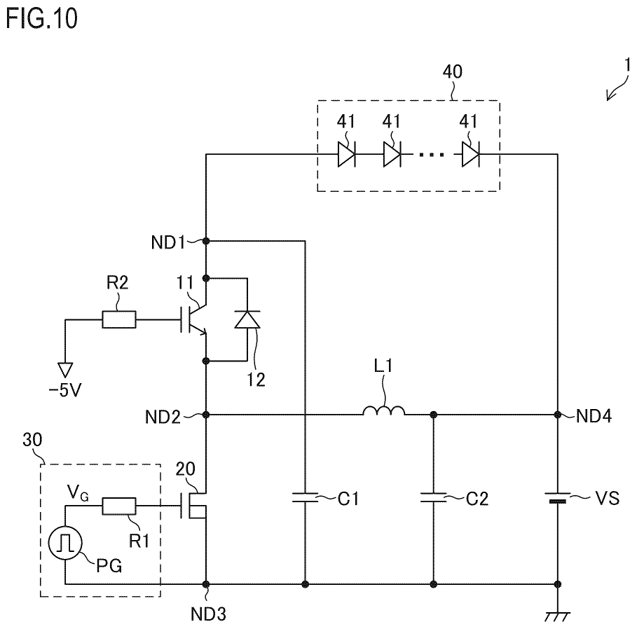

In the first and second embodiments, it may be possible to perform a first modification in which an N-channel type IGBT11 is used as the target transistor 10. FIG. 10 illustrates a circuit diagram of the element evaluation device 1 in the case where the first modification is performed on the first embodiment. IGBT is an insulated gate bipolar transistor. In the first modification, the collector and the emitter of IGBT11 are connected to the node ND1 and the node ND2, respectively. In other words, in the first modification, the voltage between the nodes ND1 and ND2 is a voltage V_{CE} between the collector and the emitter of IGBT11, and tolerance for a change in the voltage V_{CE} can be evaluated.

It is preferred to apply the gate of IGBT11 with a gate voltage to fix IGBT11 in OFF state. When the first modification is adopted, it is preferred to add a diode 12 in parallel to IGBT11. The anode and the cathode of the diode 12 are connected to the nodes ND2 and ND1, respectively, and the diode 12 has the same function as the parasitic diode 10D of FIG. 6. In other words, in the circulation operation of FIG. 6, the inductor current IL (circulation current) flows in the current loop LP3 through the diode 12. When the circulation operation of FIG. 6 is performed, it may be possible that IGBT11 is in ON state.

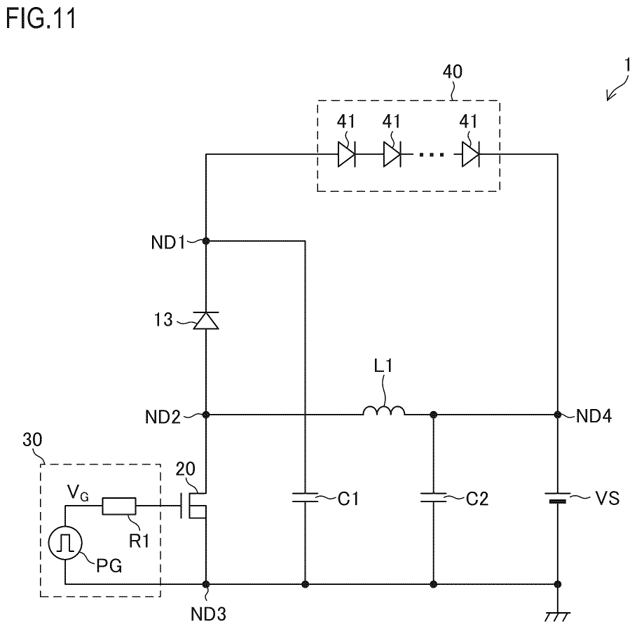

The target element may be an arbitrary type of diode (e.g., a fast recovery diode). The diode as the target element is referred to as a target diode in the following description. In other words, in the first and second embodiments, it may be possible to perform a second modification in which the target transistor 10 is replaced with the target diode. FIG. 11 illustrates a circuit diagram of the element evaluation device 1 in the case where the second modification is performed on the first embodiment. In FIG. 11, a diode 13 is the target diode. The anode of the target diode 13 is connected to the node ND2, and the cathode of the target diode 13 is connected to the node ND1. In other words, in the second modification, the voltage between the nodes ND1 and ND2 is a voltage V_{KA} between the cathode and the anode of the diode 13, and tolerance for a change in the voltage V_{KA} can be evaluated.

The type of the channel of the transistor illustrated in each embodiment is an example. Without impairing the spirit of the above description, the type of the channel of an arbitrary transistor can be changed between the P-channel type and the N-channel type.

The embodiment of the present disclosure can be appropriately modified in various manners within the scope of the technical concept recited in the claims. The embodiment described above is merely an example of the embodiment of the present disclosure, and meaning of the present disclosure and terms of the structural elements are not limited to those described in the above embodiment. The specific numeric values shown in the above description are merely examples, and it is possible to change them to various numeric values as a matter of course.

### «Additional Remarks»

Additional remarks are described below for the present disclosure of which specific structures are described in the above embodiments.

An element evaluation device (1, 1A) according to an aspect of the present disclosure has a structure (first structure) including a target element (10, 11, 13) connected between a first node (ND1) and a second node (ND2); a drive switching element (20) connected between the second node and a third node (ND3); an inductor (L1) connected between the second node and a fourth node (ND4) applied with a power supply voltage; a switching circuit (30) configured to allow the drive switching element to perform switching; a voltage generation circuit (40, 50) connected between the first node and the fourth node; and a capacitor (C1) connected between the first node and the third node. After the drive switching element is switched from ON state to OFF state, when a circulation current flows in a current loop (LP3) from the fourth node back to the fourth node via the second node, the first node, and the voltage generation circuit, the voltage generation circuit generates a voltage between the first node and the fourth node, with the first node being a high potential side.

In this way, tolerance of the target element for a change of voltage applied to the target element (a change of voltage between the first and second nodes) can be appropriately evaluated (e.g., efficiently evaluated).

The element evaluation device according to the above first structure may have a structure (second structure), in which the voltage generation circuit (40) includes one or more diodes (41) having a forward direction from the first node to the fourth node.

The element evaluation device according to the above first structure may have a structure (third structure) in which the voltage generation circuit (50) is a DC voltage source.

The element evaluation device according to the above first to third structures may have a structure (fourth structure) in which the target element is a target transistor or a target diode.

The element evaluation device according to the above first to third structures may have a structure (fifth structure), in which the target element is a target transistor (10, 11) having a drain or a collector connected to the first node, and a source or an emitter connected to the second node.

The element evaluation device according to the above fifth structure may have a structure (sixth structure), in which the target transistor (10) is a MOSFET having a drain connected to the first node and a source connected to the second node, and the MOSFET is formed of silicon carbide.

The element evaluation device according to the above fifth or sixth structure may have a structure (seventh structure) in which the target transistor is fixed to OFF state.

The element evaluation device according to any one of the above first to third structures may have a structure (eighth structure) in which the target element is a target diode (13) having a cathode connected to the first node and an anode connected to the second node.

The element evaluation device according to any one of the above first to eighth structures may have a structure (ninth structure) in which a turn-on delay time of the drive switching element is 5 nanoseconds or less.

When the turn-on delay time of the drive switching element is shortened, switching speed of the drive switching element is increased. When the switching speed of the drive switching element is increased, the above tolerance can be evaluated in a state where changing speed of the voltage applied to the target element is increased. In other words, the tolerance of the target element for high dV/dt can be evaluated.

The element evaluation device according to any one of the above first to ninth structures may have a structure (tenth structure), in which the drive switching element is constituted of a semiconductor component (120) including a semiconductor chip (121) in which a MOSFET is formed, a package (122) housing the semiconductor chip, and a drain terminal (T_{D}), a power source terminal (T_{DS}), a driver source terminal (T_{DS}) and a gate terminal (T_{G}), which are exposed from the package, a gate electrode of the MOSFET in the semiconductor chip is connected to the gate terminal, a drain electrode of the MOSFET in the semiconductor chip is connected to the second node via the drain terminal, a source electrode of the MOSFET in the semiconductor chip is connected to the third node via the power source terminal including a package inductance component (L_{S}) and is connected to the driver source terminal without going through the power source terminal, and the switching circuit supplies a gate signal (V_{G}) between the gate terminal and the driver source terminal, so as to allow the drive switching element to perform switching.

With the tenth structure, the switching speed of the drive switching element is increased. When the switching speed of the drive switching element is increased, the above tolerance can be evaluated in a state where changing speed of the voltage applied to the target element is increased. In other words, the tolerance of the target element for high dV/dt can be evaluated.

The element evaluation device according to any one of the above first to tenth structures may have a structure (eleventh structure) in which the drive switching element is a MOSFET formed of silicon carbide.

The element evaluation device according to any one of the above first to eleventh structures may have a structure (twelfth structure) in which the switching circuit allows the drive switching element to perform switching at a frequency of 10 kHz or more.

By increasing the switching frequency of the drive switching element, the above tolerance (such as a life curve) of the target element can be evaluated in a short period of time.

The element evaluation device according to any one of the above first to twelfth structures may have a structure (thirteenth structure), in which the switching circuit allows the drive switching element to perform switching at a predetermined frequency, and sets an ON time of the drive switching element to 500 nanoseconds or less in each period of switching of the drive switching element.

The element evaluation device according to any one of the above first to thirteenth structures may have a structure (fourteenth structure) in which the power supply voltage is 600 V or more with respect to the potential at the third node.

1. An element evaluation device comprising:
a target element connected between a first node and a second node;
a drive switching element connected between the second node and a third node;
an inductor connected between the second node and a fourth node applied with a power supply voltage;
a switching circuit configured to allow the drive switching element to perform switching;
a voltage generation circuit connected between the first node and the fourth node; and
a capacitor connected between the first node and the third node, wherein after the drive switching element is switched from ON state to OFF state, when a circulation current flows in a current loop from the fourth node back to the fourth node via the second node, the first node, and the voltage generation circuit, the voltage generation circuit generates a voltage between the first node and the fourth node, with the first node being a high potential side.

2. The element evaluation device according to claim 1, wherein the voltage generation circuit includes one or more diodes having a forward direction from the first node to the fourth node.

3. The element evaluation device according to claim 1, wherein the voltage generation circuit is a DC voltage source.

4. The element evaluation device according to claim 1, wherein the target element is a target transistor or a target diode.

5. The element evaluation device according to claim 1, wherein the target element is a target transistor having a drain or a collector connected to the first node, and a source or an emitter connected to the second node.

6. The element evaluation device according to claim 5, wherein the target transistor is a MOSFET having a drain connected to the first node and a source connected to the second node, and wherein the MOSFET is formed of silicon carbide.

7. The element evaluation device according to claim 5, wherein the target transistor is fixed to OFF state.

8. The element evaluation device according to claim 1, wherein the target element is a target diode having a cathode connected to the first node and an anode connected to the second node.

9. The element evaluation device according to claim 1, wherein a turn-on delay time of the drive switching element is 5 nanoseconds or less.

10. The element evaluation device according to claim 1, wherein
the drive switching element is constituted of a semiconductor component including a semiconductor chip in which a MOSFET is formed, a package housing the semiconductor chip, and a drain terminal, a power source terminal, a driver source terminal, and a gate terminal, which are exposed from the package,
a gate electrode of the MOSFET in the semiconductor chip is connected to the gate terminal,
a drain electrode of the MOSFET in the semiconductor chip is connected to the second node via the drain terminal,
a source electrode of the MOSFET in the semiconductor chip is connected to the third node via the power source terminal including a package inductance component and is connected to the driver source terminal without going through the power source terminal, and
the switching circuit supplies a gate signal between the gate terminal and the driver source terminal, so as to allow the drive switching element to perform switching.

11. The element evaluation device according to claim 1, wherein the drive switching element is a MOSFET formed of silicon carbide.

12. The element evaluation device according to claim 1, wherein the switching circuit allows the drive switching element to perform switching at a frequency of 10 kHz or more.

13. The element evaluation device according to claim 1, wherein the switching circuit allows the drive switching element to perform switching at a predetermined frequency, and sets an ON time of the drive switching element to 500 nanoseconds or less in each period of switching of the drive switching element.

14. The element evaluation device according to claim 1, wherein the power supply voltage is 600 V or more with respect to the potential at the third node.
